(19) United States
(12) Patent Application Publication
(10) Pub. No.: US 2013/0277713 A1
(43) Pub. Date: Oct. 24, 2013

(54) As/Sb Compound Semiconductors Grown on Si or Ge Substrate

(71) Applicant: NATIONAL CENTRAL UNIVERSITY, Taoyuan County (TW)

(72) Inventors: Jen-Inn Chyi, Taoyuan County (TW); Wei-Jen Hsueh, Taoyuan County (TW); Pei-Chin Chiu, Taoyuan County (TW)

(73) Assignee: NATIONAL CENTRAL UNIVERSITY, Taoyuan County (TW)

(21) Appl. No.: 13/834,100

(22) Filed: Mar. 15, 2013

(30) Foreign Application Priority Data
Apr. 18, 2012 (TW) 101113873

(51) Int. Cl. H01L 29/205

(52) U.S. Cl. CPC H01L 29/205
USPC 257/190

(57) ABSTRACT

An As(arsenic)/Sb(antimony) compound semiconductor is grown on a Si(silicon) or Ge (germanium) substrate. With the present invention, island-like growth on the Si or Ge substrate owing to lattice constant mismatch is prevented. Bad electrical isolation owing to diffusion of Ge is also prohibited. The present invention could obtain a high quality metamorphic buffer which is suitable for integrating a Si or Ge substrate with an electronic or optoelectronic device of a III/V group semiconductor.

### TECHNICAL FIELD OF THE INVENTION

This invention provides an method to grow a high quality and low defects density metamorphic buffer layer having a lattice constant between 5.6 Å and 6.1 Å on a Si(silicon) or Ge(germanium) substrate.

### DESCRIPTION OF THE RELATED ARTS

III-V material like In(Ga)As and In(Ga)Sb as transistor channel devices play an important role in digital circuit due their own low band gap and high carrier mobility. However, integration of the III-V material on Si or Ge which are the most common material in semiconductor industry remains a challenge. The defects such as anti-phase domain threading dislocation stacking faults, and twins are generated to relax the stain due the lattice mismatch between the III-V and Si/Ge substrates. Besides, the Ge out diffusion from the Ge substrate to epitaxial film results in unexpected impurity doping in the devices and affects the transistor properties. Several buffer structures have been proposed to relax the strain and suppress Ge out-diffusion. A prior art is revealed in “Growth of very-high-mobility AlGaSb/InAs high-electron-mobility transistor structure on Si substrate for high speed electronic applications”, Applied Physics Letters. 90 (2007) 023509, by Y. C. Lin, et al., where a high electron mobility transistor (HEMT) of AlGaSb/InAs (Al:allunium, In:indium) is grown on a Si substrate. Almost 6 micrometers (μm) of epitaxial layers of SiGe/Ge/GaAs/Al(Ga)Sb metamorphic buffers are grown on the Si substrate by different equipment and extend the lattice constant of buffer layer to 6.1 A to integrate the high mobility InAs HEMT structure. Thus, the procedure becomes complex and the metamorphic layer becomes over-thick.

Another prior art is revealed in “Semiconductor buffer architecture for III-V devices on silicon substrate”, U.S. Pat. No. 8,034,675 B2 by Mantu K. Hudait, et al.; and “Metamorphic buffer on small lattice constant substrates” United States Patent Application Publication, 2006/00171063, Jan. 26,(2006) by Luke F. Lester et al. AlSb, GaSb or InAlSb is used for forming a buffer layer on Si. However, when these materials are directly grown on the Si substrate as buffer layer, large lattice mismatch (over 13%) results in island-like crystals and planar defects like twins and stacking faults easily appear. Such defects become carrier scattering centers and degrade the transport properties.

Another prior art is revealed in “High-quality III-V semiconductor MBE growth on Ge/Si virtual substrates for metal-oxide-semiconductor device fabrication”, J. Crystal Growth 311, 1962-1971(2009) by Donghun Choi et al. A thick GaAs is grown at low temperature before growth of InGaAs channel devices. The layer can minimum the Ge out-diffusion to the buffer and further weaken the isolation of the buffer layer. However, it is not easy to obtain high quality crystal when thick GaAs layer is gown at unsuitable growth temperature. (The suitable growth temperature of GaAs is 580° C.).

In summary the prior arts above have disadvantages as follows:

(1) For growing a material having a larger lattice constant than Si, such as InAs, a thick buffer layer material of SiGe, Ge and GaAs has to be grown at first by different equipment for transforming the lattice constant to be close to that of an active layer. Thus, the procedure becomes complex and the metamorphic layer becomes over-thick.

(2) A material (like GaSb, AlSb or InAlSb) having a large lattice constant than that of the Si substrate is directly grown on the Si substrate to as a metamorphic layer to relax the strain. However, a lot of planar defects such as micro-twins and stacking faults results from island growth are generated to relax the strain. These planar defects result in the uneven surface and as a carrier scattering centers to degrade the transport properties.

(3) To prevent Ge diffusing upwardly and further affect electrical isolation of the metamorphic layer. Thick buffer grown on Ge under very low temperature is needed. As a result, the material quality is very bad due to unsuitable growth temperature.

Hence, the prior arts do not fulfill all users' requests on actual use.

### SUMMARY OF THE INVENTION

The main purpose of the present invention is to provide a thin high quality and low defects density metamorphic structure of Ga(As)Sb, on Si or Ge substrate, where through adjusting content of Sb, a lattice constant of the structure is adjusted to be extended from 5.6 Å to 6.1 Å.

The second purpose of the present invention is to reduce the twins and stacking faults in metamorphic buffer layer by promoting the 2D growth of initial layer on Si or Ge substrate due to less lattice mismatch between the nucleation layer and Si substrate.

The third purpose of the present invention is to provide a metamorphic layer as a blocking layer to prevent Ge out-diffusion. Because the malting point of Sb compounds is low, this metamorphic layer can be grown at low temperature and suppress the Ge out-diffusion while keeping a good buffer material quality.

To achieve the above purposes, the present invention is an As/Sb compound semiconductor grown on a Si or Ge substrate, comprising a nucleation layer and at least one graded layer, where the nucleation layer is grown on a substrate; the nucleation layer is a GaAs layer; the nucleation layer has a thickness smaller than 100 nanometer (nm); the at least one graded layer is grown on the nucleation layer; the graded layer is a GaAsSb graded layer; and the at least one graded layer has a thickness between 5 nm and 2000 nm. Accordingly, a novel As/Sb compound semiconductor metamorphic layer grown on a Si or Ge substrate is obtained.

### BRIEF DESCRIPTIONS OF THE DRAWINGS

The present invention will be better understood from the following detailed description of the preferred embodiment according to the present invention, taken in conjunction with the accompanying drawings, in which

FIG. 1 is the view showing the preferred embodiment according to the present invention;

FIG. 1A to FIG. 1L are the views showing the steps of the first method for fabricating the present invention;

FIG. 2A to FIG. 2L are the views showing the steps of the second method; and

FIG. 3A to FIG. 3L are the views showing the steps of the third method.

FIG. 4A to FIG. 4E are the views showing the steps of the fourth method.

### DESCRIPTION OF THE PREFERRED EMBODIMENT

The following description of the preferred embodiment is provided to understand the features and the structures of the present invention.

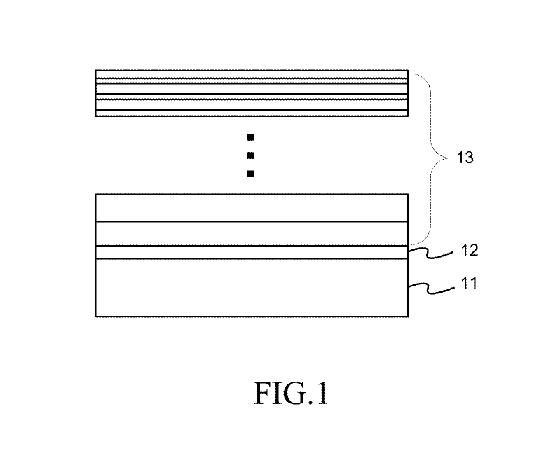

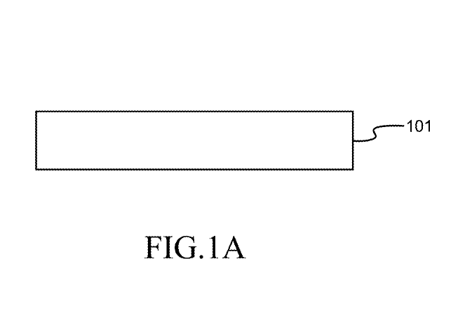

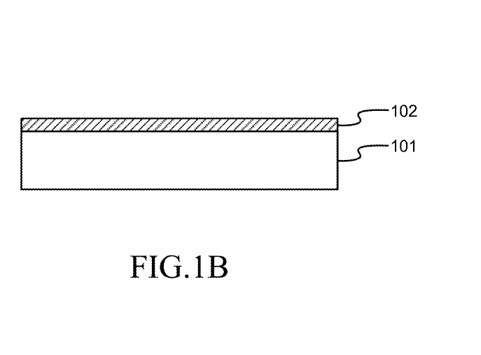

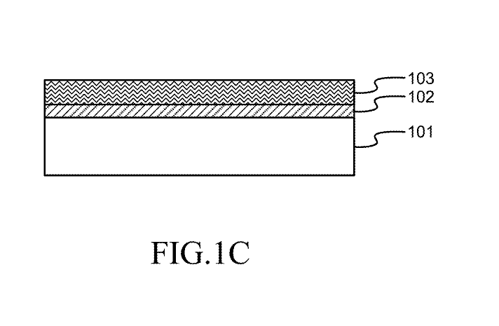

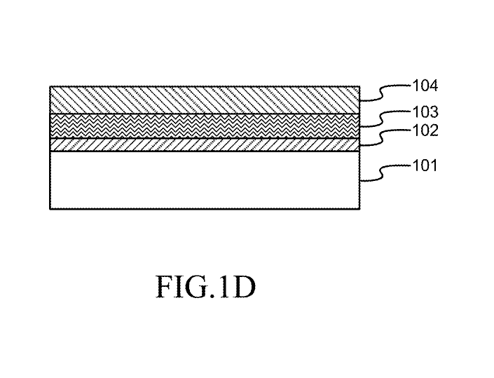

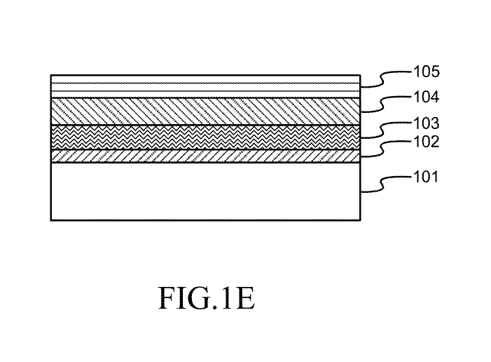

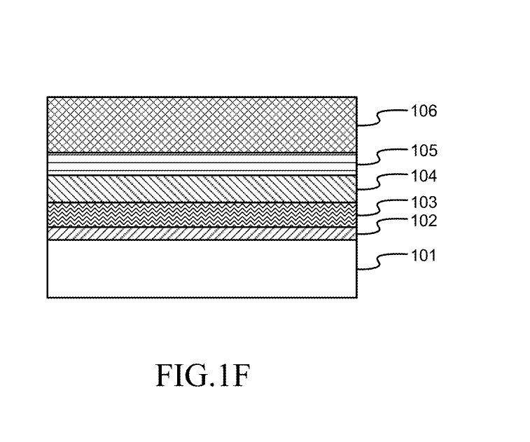

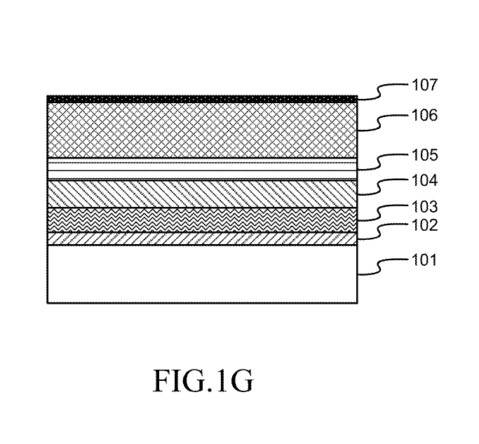

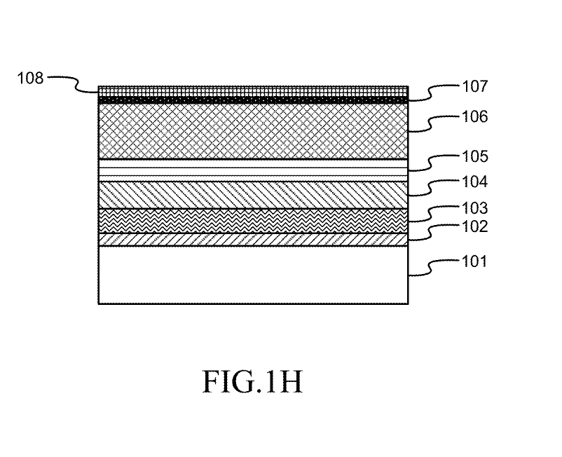

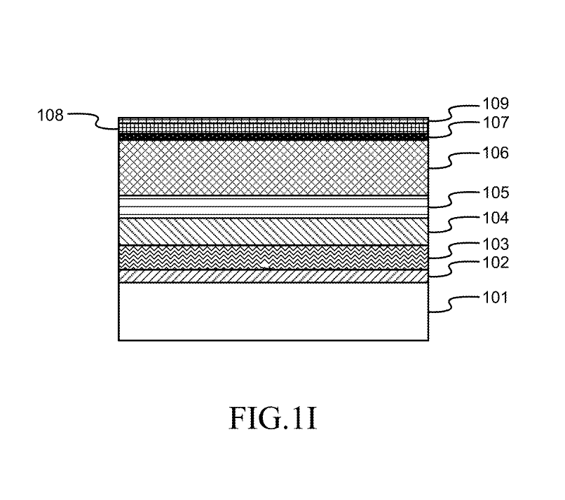

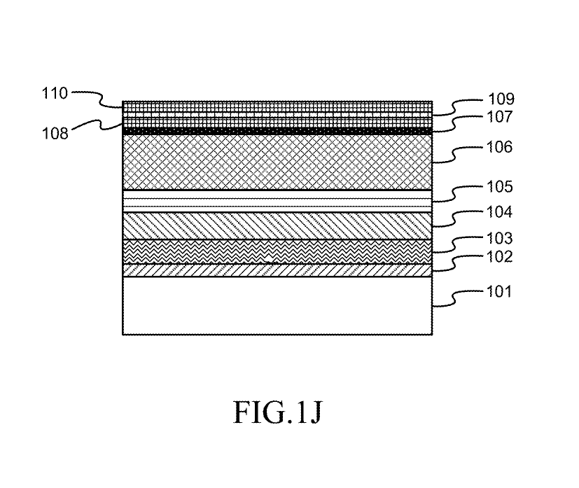

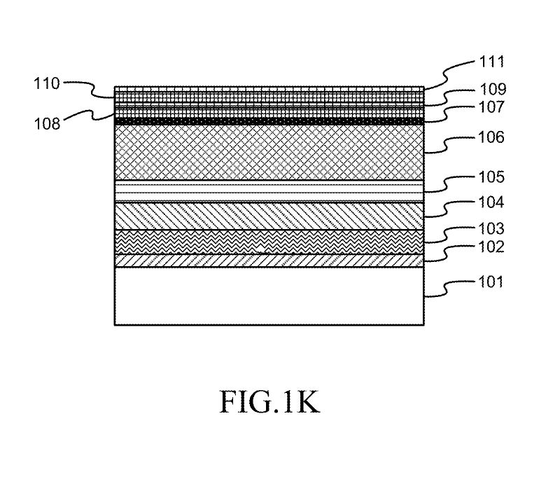

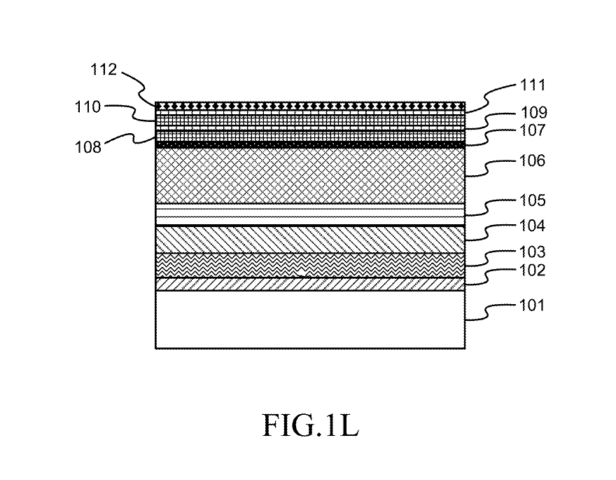

Please refer to FIG. 1, which is a view showing a preferred embodiment according to the present invention. As shown in the figure, the present invention is an As(arsenic)/Sb(antimony) compound semiconductor grown on a Si(silicon) or Ge(germanium) substrate, comprising a substrate 11, a nucleation layer 12 and at least one graded layer 13, where the nucleation layer 12 is deposited on the substrate 11; the nucleation layer 12 is a GaAs(Ga: gallium) nucleation layer and has a thickness smaller than 100 nanometers (nm); the at least one graded layer 13 is deposited on the nucleation layer 12; the at least one graded layer 13 is a GaAsSb graded layer; and the at least one graded layer 13 has a thickness between 5 nm and 2000 nm.

Please refer to FIG. 1A to FIG. 1L, which are views showing steps of a first method to fabricate the present invention on Si substrate. As shown in the figures, a method for fabricating the present invention with a Si or Ge substrate and a material of GaAsSb is shown, which method is also suitable for fabricating the present invention with any substrate and any material of III/V group compound.

The method hereby provided is to grow an InAs(In: indium) high electron mobility transistor on a Si substrate, At first, an RCA cleaning method is used with a solution, like an HF acid, for removing an oxidation layer on the Si substrate 101, as shown in FIG. 1A. Then, after removing the oxidation layer, the substrate 101 is put into an epitaxy chamber for cleaning leftover oxidants on surface under a temperature of 700˜1000 Celsius degrees (° C.) for 1 hour. Then, a 30 Å nucleation layer 102 of GaAs is grown on the substrate 101 under 300° C. at a ratio about 10 of V/III group through migration enhanced epitaxy (MEE), as shown in FIG. 1B. Then, a first graded layer 103 of GaAsₓSb₁₋ₓ (x=0.95), which has a thickness of 500 Å, is grown on the nucleation layer 102 under 500° C., as shown in FIG. 1C. Then, a second graded layer 104 of GaAsₓSb₁₋ₓ (x=0.85, x is smaller than the x of the first graded layer), which has a thickness of 500 Å, is grown on the first graded layer 103 under 500° C., as shown in FIG. 1D. Then, a third graded layer 105 of GaAsₓSb₁₋ₓ (x=0.75, x is smaller than the x of the second graded layer), which has a thickness of 500 Å, is grown on the second graded layer 104 under 500° C., as shown in FIG. 1E. Then, a buffer layer 106 of AlGaSb (Al: aluminum),which has a thickness of 1 micrometer (μm), is grown on the third graded layer 105 under 540° C., as shown in FIG. 1F. Then, a 130 Å channel layer 107 of InAs is grown on the buffer layer 106 under 480° C., as shown in FIG. 1G. Then, an AlGaSb spacer layer 108, a ΔTe(tellurium) n-type doped layer 109 and an AlGaSb upper barrier layer 110 are grown on the channel layer 107, as shown in FIG. 1H to FIG. 1J. At last, a 50 Å cover layer 111 of InAlAs and a 20 Å ohmic contact layer 112 of InAs are grown on the upper barrier layer 110, as shown in FIG. 1K and FIG. 1L. Growth of above nucleation layer and graded layers in this present invention is through molecular beam epitaxy (MBE) or metal-organic vapor phase epitaxy (MOVPE).

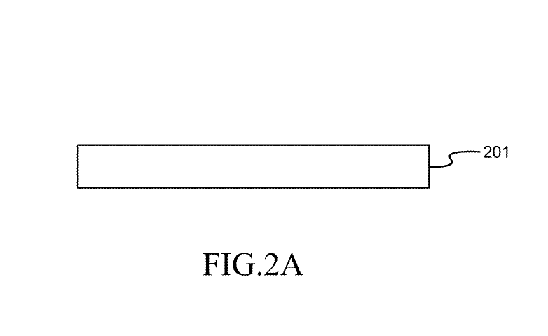

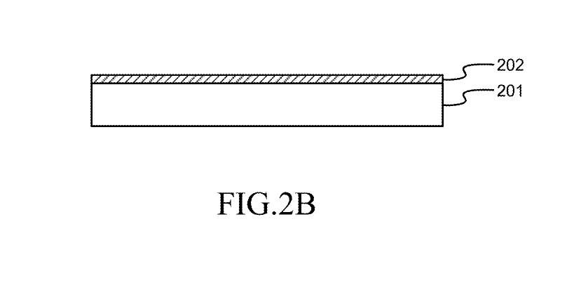

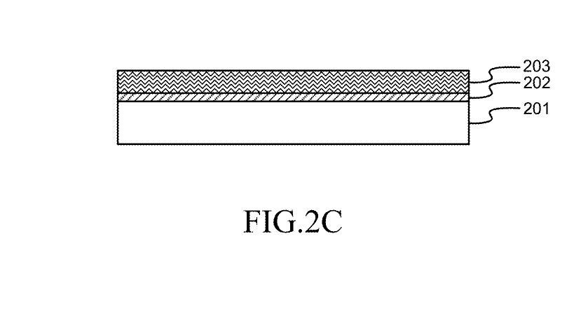

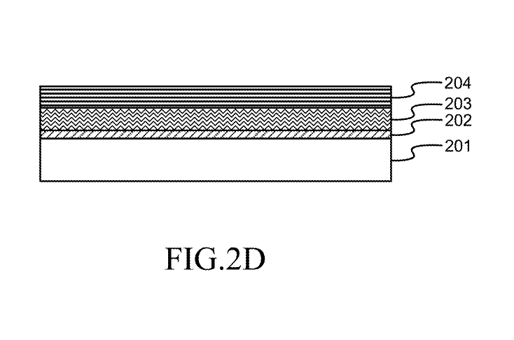

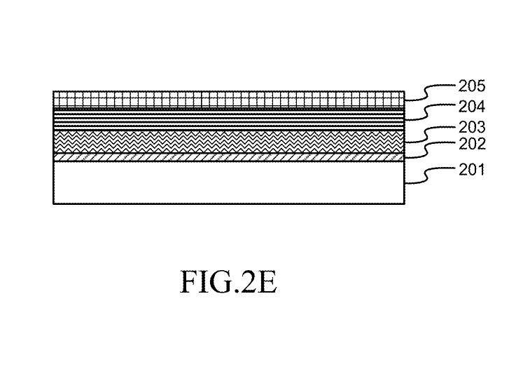

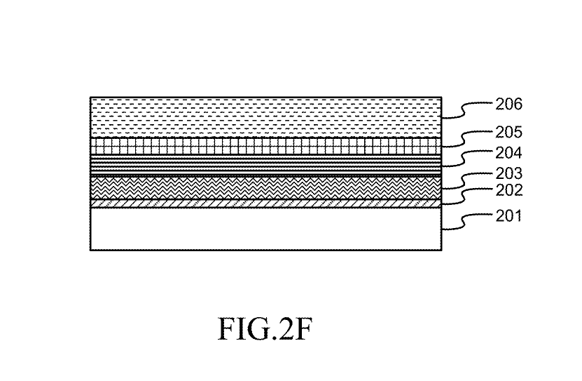

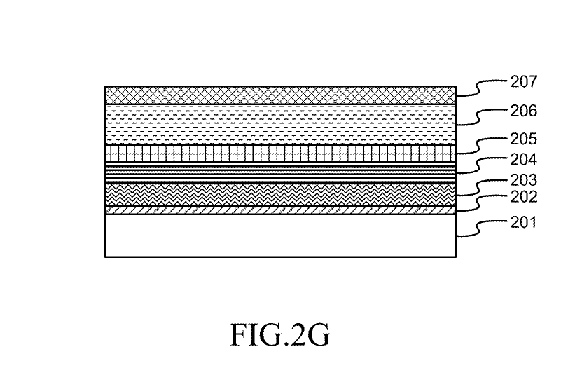

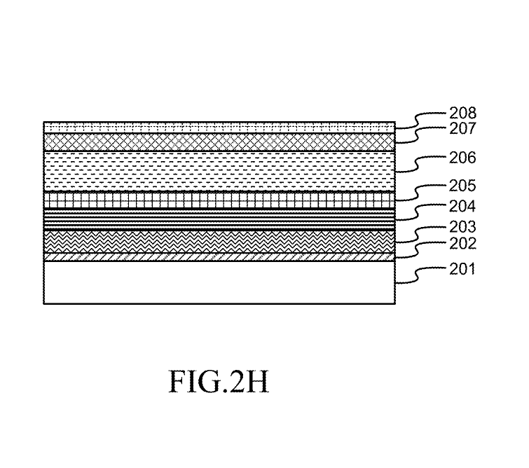

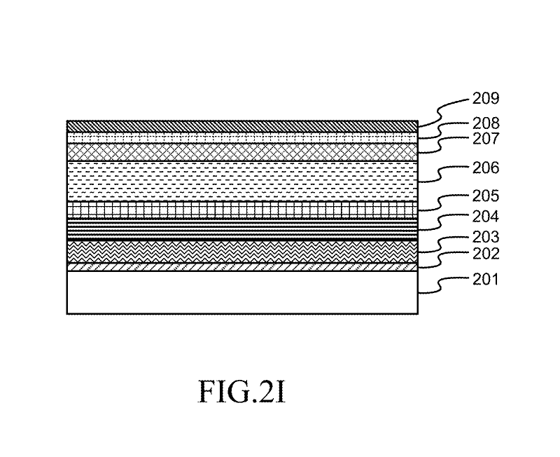

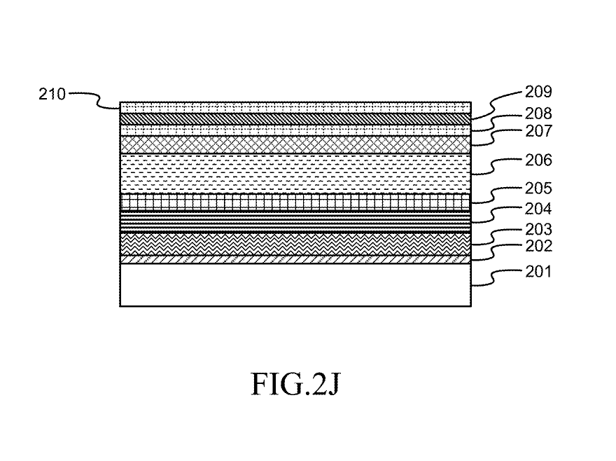

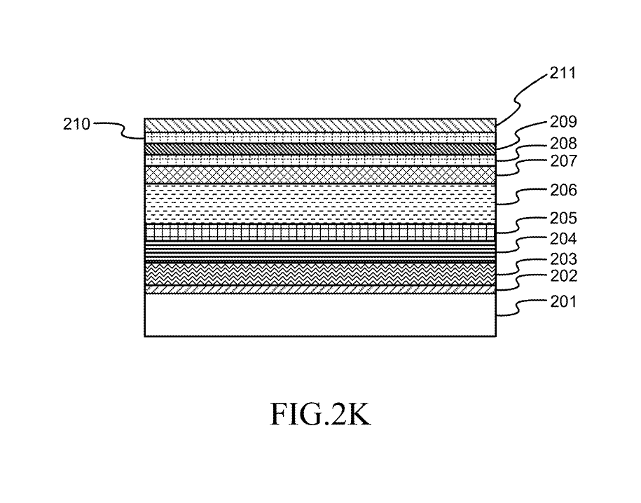

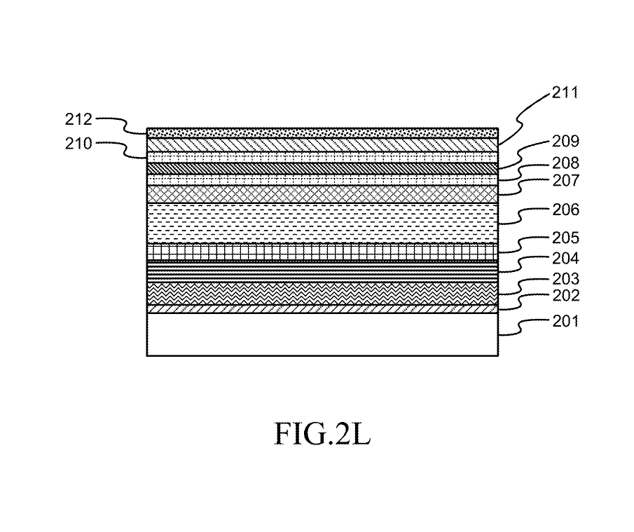

Please refer to FIG. 2A to FIG. 2L, which are views showing steps of a second method for fabricating the present invention. As shown in the figures, at first, an RCA cleaning method is used with a solution, like an HF acid, for removing an oxidation layer on a Si substrate 201, as shown in FIG. 2A. Then, after removing the oxidation layer, the substrate 201 is put into an epitaxy chamber for cleaning leftover oxidants on surface under a temperature of 700˜1000° C. for 1 hour. Then, a 30 Å nucleation layer 202 of GaAs is grown on the substrate 201 under 300° C. at a ratio about 10 of V/III group through MEE, as shown in FIG. 2B. Then, a first graded layer 203 of GaAsₓSb₁₋ₓ (x=0.95), which has a thickness of 500 Å, is grown on the nucleation layer 202 under 480° C., as shown in FIG. 2C. Then, a second graded layer 204 of GaAsₓSb₁₋ₓ (x=0.85, x is smaller than the x of the first graded layer), which has a thickness of 500 Å, is grown on the first graded layer 203 under 480° C., as shown in FIG. 2D. Then, a third graded layer 205 of GaAsₓSb₁₋ₓ (x=0.85, x is smaller than the x of the second graded layer), which has a thickness of 500 Å, is grown on the second graded layer 204 under 480° C., as shown in FIG. 2E. Then, a 1 μm buffer layer 206 of AlGaSb is grown on the third graded layer 205 under 540° C., as shown in FIG. 2F. Then, a 75 Å channel layer 207 of InₓGa₁₋ₓSb (x=0.4) is grown on the buffer layer 206 under 430° C., as shown in FIG. 2G. Then, a 50 Å spacer layer 208 of AlGaSb, a ΔBe(beryllium) p-type doped layer 209 and an 30 Å AlGaSb upper barrier layer 210 are grown on the channel layer 207, as shown in FIG. 2H to FIG. 2J. At last, a 50 Å cover layer 211 of InAlAs and a 20 Å ohmic contact layer 212 of InAs are grown on the upper barrier layer 210, as shown in FIG. 2K and FIG. 2L.

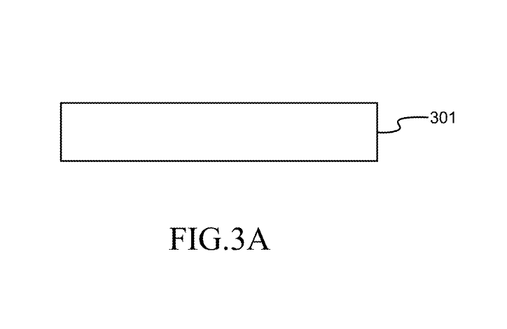

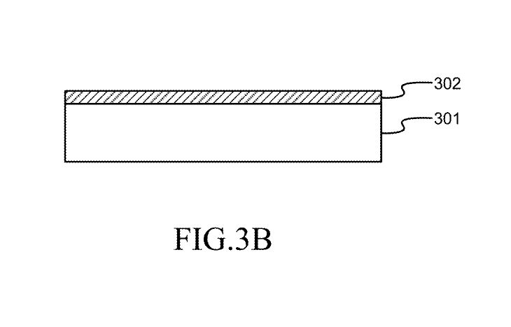

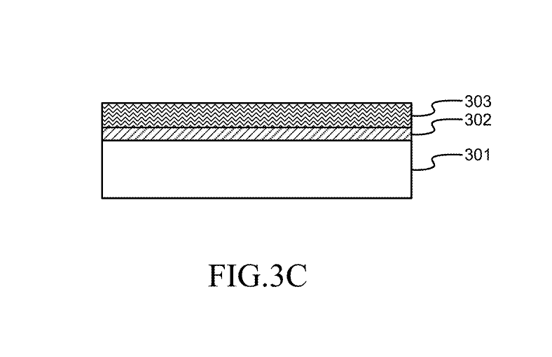

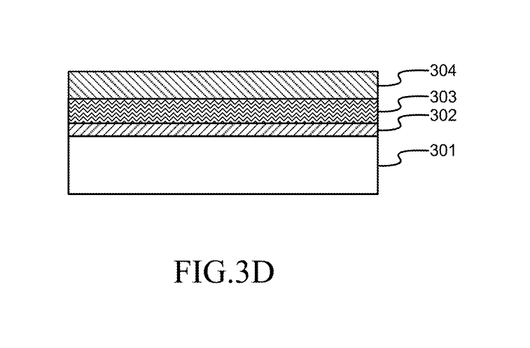

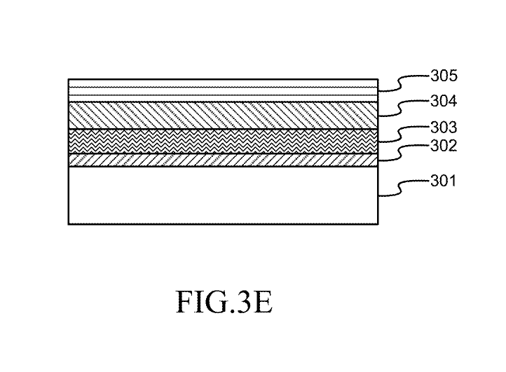

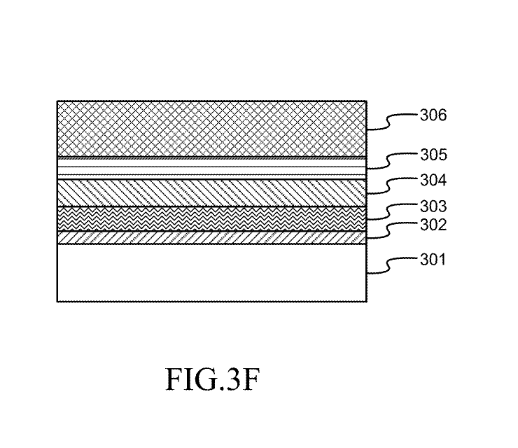

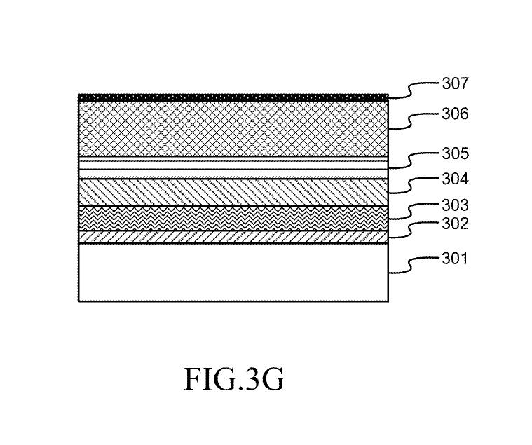

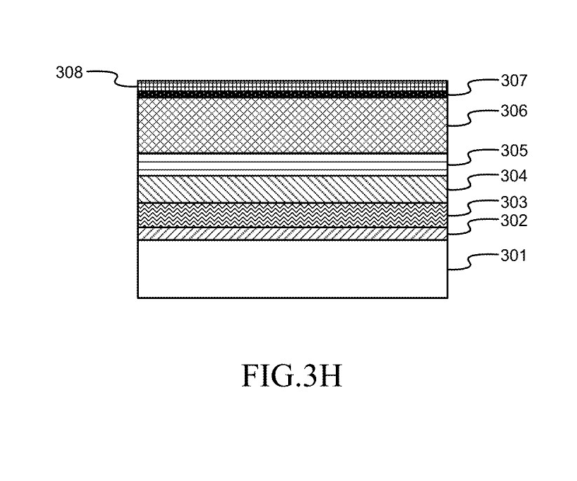

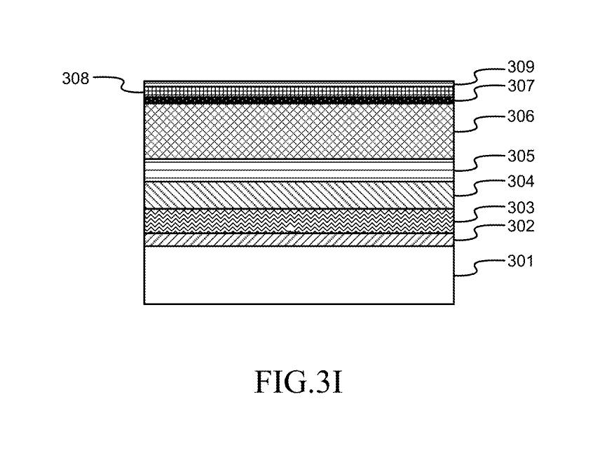

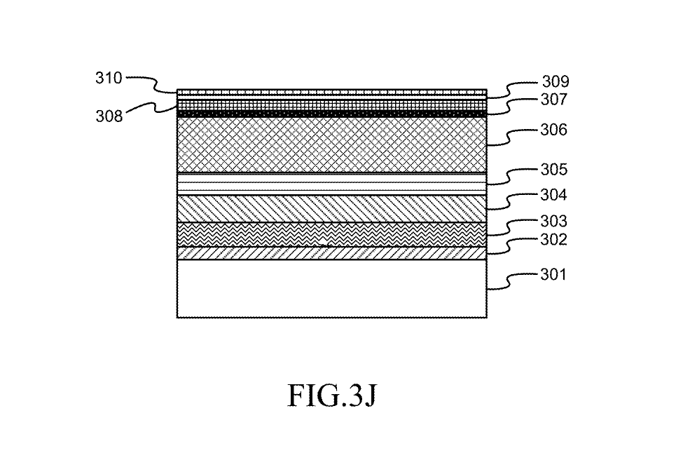

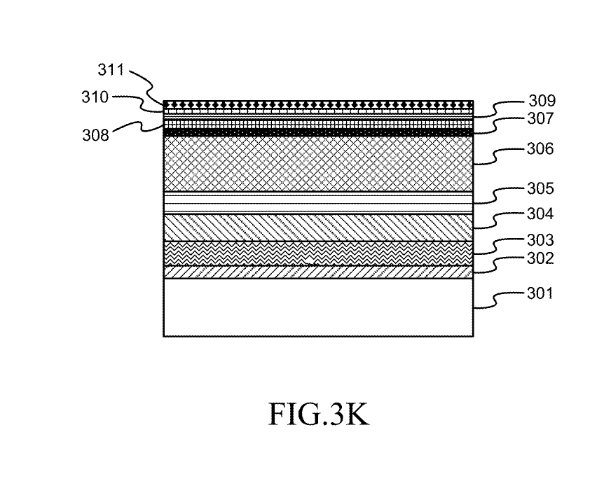

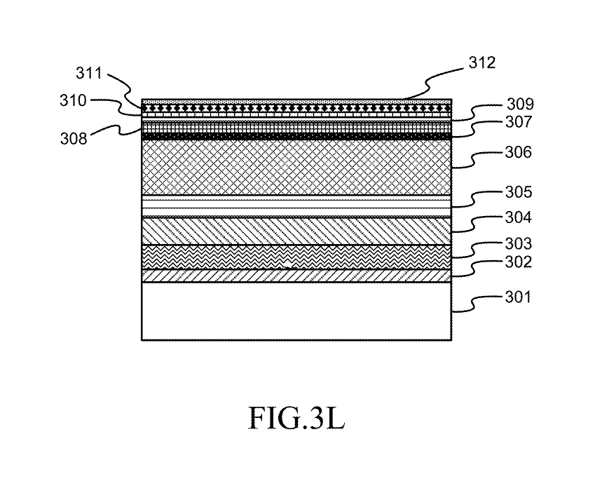

Please refer to FIG. 3A to FIG. 3L, which are views showing steps of a third method for fabricating the present invention. As shown in the figures, at first, a cleaning process is used with an HF acid solution, for removing an oxidation layer on a Ge substrate 301, as shown in FIG. 3A. Then, after removing the oxidation layer, the substrate 301 is put into an epitaxy chamber for cleaning leftover oxidants on surface under a temperature of 600° C. for 30 minutes. Then, a 30 Å nucleation layer 302 of GaAs is grown on the substrate 301 under 300° C. at a ratio about 10 of V/III group through MEE, as shown in FIG. 3B. Then, a first graded layer 303 of GaAsₓSb₁₋ₓ (1>x>0.51), which has a thickness of 500 Å, is grown on the nucleation layer 302 under 480° C., as shown in FIG. 3C. Then, a second graded layer 304 of GaAsₓSb₁₋ₓ (1>x>0.51, x is smaller than the x of the first graded layer), which has a thickness of 500 Å, is grown on the first graded layer 303 under 480° C., as shown in FIG. 3D. Then, a third graded layer 305 of GaAsₓSb₁₋ₓ (1>x≧0.51, x is smaller than the x of the second graded layer), which has a thickness of 500 Å, is grown on the second graded layer 304 under 480° C., as shown in FIG. 3E. Then, a 0.5 μm buffer layer 306 of InₓAl₁₋ₓAs (x=0.52) is grown on the third graded layer 305 under 520° C., as shown in FIG. 3F. Therein, lattice constant of the buffer layer does not have to match with that of the previous layer and the buffer layer can be used as a barrier layer. Then, a 50 Å channel layer 307 of InₓGa₁₋ₓAs (x=0.75) is grown on the buffer layer 306 under 480° C., as shown in FIG. 3G. Then, a 50 Å spacer layer 308 of InₓAl₁₋ₓAs (x=0.52) is grown on the channel layer 307, as shown in FIG. 3H. Then, a ΔSi n-type doped layer 309 and a 20 Å upper barrier layer 310 of InₓAl₁₋ₓAs (x=0.52) are grown on the spacer layer 308, as shown in FIG. 3I and FIG. 3J. At last, a 20 Å etching stop layer 311 of InP and a 50 Å cover layer 312 of InₓGa₁₋ₓAs (x=0.52) are grown on the upper barrier layer 310, as shown in FIG. 3K and FIG. 3L.

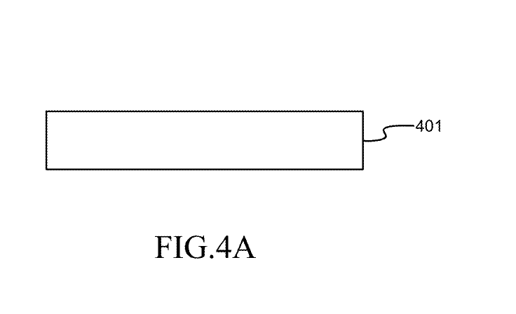

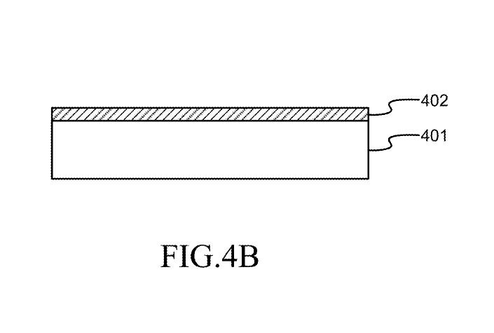

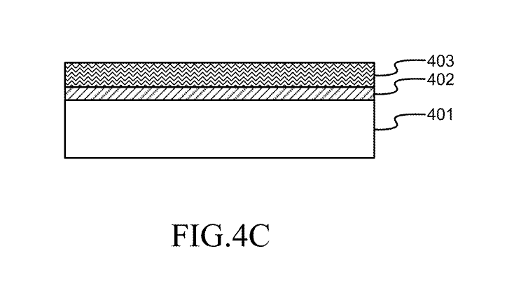

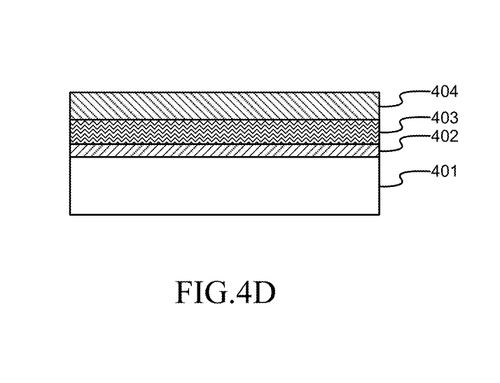

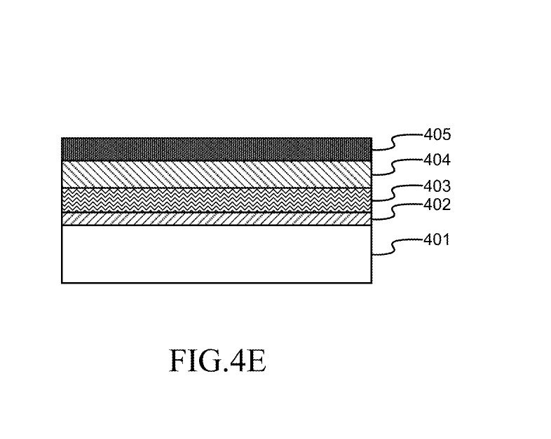

Please refer to FIG. 4A to FIG. 4L, which are views showing steps of a fourth method for fabricating the present invention. As shown in the figures, at first, a cleaning process is used with an HF acid solution, for removing an oxidation layer on a Ge substrate 401, as shown in FIG. 4A. Then, after removing the oxidation layer, the substrate 401 is put into an epitaxy chamber for cleaning leftover oxidants on surface under a temperature of 600° C. for 30 minutes. Then, a 30 Å nucleation layer 402 of GaAs is grown on the substrate 401 under 300° C. at a ratio about 10 of V/III group through MEE, as shown in FIG. 4B. Then, a first graded layer 403 of GaAsₓSb₁₋ₓ (x=0.95), which has a thickness of 500 Å, is grown on the nucleation layer 402 under 480° C., as shown in FIG. 4C. Then, a second graded layer 404 of GaAsₓSb₁₋ₓ (0.95>x≧0.51, x is smaller than the x of the first graded layer), which has a thickness of 500 Å, is grown on the first graded layer 403 under 480° C., as shown in FIG. 4D. Then, a 0.5 μm buffer layer 405 of InP is grown on the second graded layer 404 under 480° C., as shown in FIG. 4E.

Thus, the present invention directly uses GaAs as a nucleation layer and grows a graded layer of GaAsSb to form a metamorphic layer for integrating a Si or Ge substrate and layers grown upon. In one embodiment, the As in the graded layer can be replaced by P to form GaPSb. By adjusting a ratio of As/P to Sb, lattice constant of the graded layer is rotated to be close to those of the layers grown upon, like In_{0.52}Al_{0.48}As buffer layer and AlGaSb layer, etc. Or, the graded layer can be added with Al to form AlGaAsSb for adjusting energy band and increase the isolation of graded layer. In one embodiment, graded layers can be linear graded by linear tuning the flux of Sb and As/P. Because the lattice mismatch between GaAs, Si or Ge substrate is small, the possibility of island-like growth and formation of twins on the Si or Ge substrate is reduced. Besides, the suitable growth temperature of GaAsSb graded layer is rather-low so the whole structure can be grown under low temperature to prevent the Ge out-diffusion and unexpected Ge doping in buffer layer while keeping crystal quality. The nature surfactant effect of Sb also improves the surface morphology of GaAsSb.

Accordingly, the present invention has the following advantages:

1. The present invention can fabricate a metamorphic buffer layer by using general III-V materials and a simple procedure.

2. The present invention can prove a high quality and low defects density metamorphic buffer layer where lattice constant is from 5.6 Å to 6.1 Å depending on the Sb content in the graded buffer layer. III/V group compound semiconductor devices with similar lattice constant can be effectively integrated with a Si or Ge substrate by this invention.

3. A nucleation layer of GaAs is formed on the Si substrate and lattice constants of GaAsSb graded layer grown upon are adjusted for preventing island-like growth and planar defects of a metamorphic layer on the substrate.

4. The present invention uses a GaAs/GaAsSb layer to form high quality metamorphic layers and suppress additional Ge doping in the buffer layer.

To sum up, the present invention is an As/Sb compound semiconductor grown on a Si or Ge substrate, where a nucleation layer and a graded layer are grown on a Si or Ge substrate to form a high quality metamorphic layer for avoiding island-like growth and obtaining a flat epitaxy layer; stress is released through changing different content ratio of Sb; the metamorphic layer can be grown at low temperature and Ge is prevented from diffusion from below for avoiding electric leakage; and thus, the present invention is especially suitable for integrating a high-speed device or an optoelectronic device on a Si or Ge substrate.

The preferred embodiment herein disclosed is not intended to unnecessarily limit the scope of the invention. Therefore, simple modifications or variations belonging to the equivalent of the scope of the claims and the instructions disclosed herein for a patent are all within the scope of the present invention.

What is claimed is:

1. An As/Sb compound semiconductor grown on a Si substrate, comprising
a substrate;
a nucleation layer, said nucleation layer being deposited on said substrate, said nucleation layer being a GaAs layer, said nucleation layer having a thickness smaller than 100 nanometer (nm); and at least one graded layer, said at least one graded layer being deposited on said nucleation layer, said graded layer being a GaAsSb graded layer, said at least one graded layer having a thickness between 5 nm and 2000 nm.

2. The semiconductor according to claim 1, wherein said nucleation layer is made of a material selected from a group consisting of AlₓGa₁₋ₓAs, AlₓGa₁₋ₓP, AlₓGa₁₋ₓP_{y}As_{1-y} and AlₓGa₁₋ₓP_{y}Sb_{1-y}; 0≦x≦1; 0<y≦1.

3. The semiconductor according to claim 1, wherein said at least one graded layer is made of a material selected from a group consisting of AlₓGa₁₋ₓAs_{y}Sb_{1-y} and AlₓGa₁₋ₓP_{y}Sb_{1-y}; 0≦x≦1; and 0≦y<1; and wherein concentration of Sb is larger than that of nucleation layer and linear-graded or step-graded increased in said graded layer.

4. The semiconductor according to claim 1, is grown by molecular beam epitaxy (MBE) and/or metal-organic vapor phase epitaxy (MOVPE).

5. An As/Sb compound semiconductor grown on a Ge substrate, comprising
a substrate;
a nucleation layer, said nucleation layer being deposited on said substrate, said nucleation layer being a GaAs layer, said nucleation layer having a thickness smaller than 100 nanometer (nm); and
at least one graded layer, said at least one graded layer being deposited on said nucleation layer, said graded layer being a GaAsSb graded layer, said at least one graded layer having a thickness between 5 nm and 2000 nm.

6. The semiconductor according to claim 5, wherein said nucleation layer is made of a material selected from a group consisting of AlₓGa₁₋ₓAs, (0≦x≦1; 0<y≦1), and AlₓGa₁₋ₓP_{y}Sb_{1-y}; 0<y≦0.68.

7. The semiconductor according to claim 5, wherein said at least one graded layer is made of a material selected from a group consisting of AlₓGa₁₋ₓAs_{y}Sb_{1-y},(0≦x≦1; and 0≦y<1); and AlₓGa₁₋ₓP_{y}Sb_{1-y}; 0≦x≦1; and 0≦y<0.68; and wherein concentration of Sb is larger than that of nucleation layer and linear-graded or step-graded increased in said graded layer.

8. The semiconductor according to claim 5, is grown by molecular beam epitaxy (MBE) and/or metal-organic vapor phase epitaxy (MOVPE).
